(19) United States
(12) Patent Application Publication
(10) Pub. No.: US 2025/0133764 A1
(43) Pub. Date: Apr. 24, 2025

(54) SEMICONDUCTOR DEVICE AND POWER CONVERSION DEVICE USING SAME

(71) Applicant: Minebea Power Semiconductor Device Inc., Ibaraki (JP)

(72) Inventors: Tomoyuki MIYOSHI, Tokyo (JP); Tomoyasu FURUKAWA, Tokyo (JP)

(21) Appl. No.: 18/835,745

(22) PCT Filed: Oct. 25, 2022
(86) PCT No.: PCT/JP2022/039707

§ 371 Date: Aug. 5, 2024

(30) Foreign Application Priority Data
Feb. 9, 2022 (JP) 2022-018486

(51) Int. Cl. H10D 30/60; H02M 7/00; H10D 12/00; H10D 64/27

(52) U.S. Cl. CPC H10D 30/611; H10D 12/481; H10D 64/512; H02M 7/003

(57) ABSTRACT

Provided is a highly reliable semiconductor device having both a low conduction loss and a low switching loss, and, at the same time, can enhance turn-off cut-off resistance. The semiconductor device includes a switching gate and a carrier control gate that are driven independently of each other, and is characterized by comprising, as viewed in plan, a central region cell, a peripheral region cell surrounding the circumference of the central region cell, and a terminal region surrounding the circumference of the peripheral region cell, in which the central region cell includes a switching element having the switching gate and the carrier control gate, and the peripheral region cell is disposed between the central region cell and the terminal region, the switching element of the peripheral region cell having a gate only composed of the carrier control gate.

### TECHNICAL FIELD

The present invention relates to the structure of a semiconductor device, and particularly to a technique effectively applicable to a power semiconductor device for a power control.

### BACKGROUND ART

Global warming has become an important and urgent task to be solved in the whole world, and the degree of expectation of contribution of a power electronics technique has been increasing as one of countermeasures to overcome such a task problem. Particularly, aiming at the acquisition of higher efficiency of an inverter that performs a power conversion function, there has been a demand for lowering the power consumption of an insulated gate bipolar transistor (IGBT) that constitutes the inverter that performs a power switching function, and a power semiconductor device that is mainly formed of a diode that performs a rectifying function.

FIG. 25 illustrates a partial circuit diagram of a typical inverter. To an IGBT 97 that includes an insulation gate terminal 98, a diode 99 is connected to the IGBT 97 in a reverse parallel mode. The inverter is configured such that electricity is supplied to the inverter from a direct current power source 96, and controls electricity supplied to an inductive load 95 connected to the inverter by applying a voltage to an insulation gate terminal 98 of the IGBT 97 and by repeating turning on and turning off at a high speed. The inductive load 95 is, for example, a motor (electric motor)

The IGBT 97 and the diode 99 generate a conduction loss at the time of conduction, and generate a switching loss at the time of switching. Accordingly, to realize the miniaturization and the acquisition of high efficiency of the inverter, it is necessary to reduce a conduction loss and a switching loss of the IGBT 97 and the diode 99. In this case, the switching loss is constituted of a turn-on loss and a turn-off loss that the IGBT 97 generates and a recovery loss that the diode 99 generates at the time of turning on the inverter.

As a technique for reducing a conduction loss and a turn-off loss of the IGBT, for example, there has been known a technique described in the patent literature 1 relating to the IGBT structure of a double gate type (also referred to as a dual gate type) having a gate where that can perform two independent controls.

FIG. 26 is a cross-sectional view of the IGBT described in the patent literature 1. Both a gate Gs and a gate Gc have a trench shape. With respect to an emitter electrode 7, when a high voltage is applied to an insulation gate electrode 91 of the gate Gs and an insulation gate electrode 92 of the gate Gc, an electron layer that is an inversion layer is generated on an interface of a gate electrode of a p type well layer 2. With such a configuration, when a forward voltage is applied between a collector electrode 8 and the emitter electrode 7, electron carriers are injected into an n-type drift layer 1 from the emitter electrode 7 via an electron layer formed on a surface of the insulation gate electrode (Gs) 91 and a surface of the insulation gate electrode (Gc) 92, hole carriers are extracted from a p type collector layer 4, and the conductivity modulation is generated in the n-type drift layer 1 so that the IGBT is brought into a conduction state.

Next, at the time of turning off the IGBT, the carriers that contribute to the conductivity modulation by applying a voltage of less than a threshold voltage that does not form an inversion layer on an interface of a gate electrode of a p type well layer 2 to a gate are discharged to the emitter electrode 7 and the collector electrode 8 so that the IGBT is shifted to a non-conduction state. An electric power loss referred to as a turn-off loss is generated due to a current generated and an inverse direction voltage applied to the emitter electrode 7 and the collector electrode 8 at this point of time.

In this structure having the gate which can perform two independent controls, immediately before turning off the IGBT, it is possible to apply a voltage less than a threshold voltage to one insulation gate electrode (Gc) 92 prior to the insulation gate electrode (Gs) 91 and hence, conductivity modulation can be suppressed whereby it is possible to temporarily form a drift region where concentration of carriers is reduced. Accordingly, a current generated by carriers discharged at the time of turning off the IGBT can be reduced and, at the same time, a reverse direction voltage is applied between the collector electrode 8 and the emitter electrode 7 at a high speed whereby a turn-off loss can be reduced.

That is, the patent literature 1 discloses a technique where by changing a gate bias applied to the insulation gate electrode (Gs) 91 and the insulation gate electrode (Gc) 92 immediately before a conduction state and immediately before a non-conduction state respectively, it is possible to dynamically control the concentration of carriers accumulated in the n-type drift layer 1. With such a control, a loss generated at the time of turning off an IGBT can be reduced.

Further, as another mode of a double gate type, other technique that reduces a current at the time of turning off an IGBT by temporarily lowering the concentration of carriers accumulated in the vicinity of a collector region, for example, a technique relating to the structure where two IGBTs having different collector injection efficiencies are connected in parallel to each other is known by the patent literature 2, for example.

FIG. 27 is a circuit diagram of the IGBT described in the patent literature 2. The IGBT is constituted of two IGBTs 33, 34 having different structures, and performs a switching function of IGBT by connecting two IGBTs 33, 34 in parallel. Two IGBTs 33, 34 are IGBTs having different structures where the carrier injection efficiency is high and an ON voltage is low in the IGBT 33, and the carrier injection efficiency is low and an ON voltage is high in the IGBT 34. The gates 35, 36 of these IGBTs 33, 34 are independently controlled.

The carrier injection efficiency is adjusted based on impurity concentration in a collector region of the IGBT 33, 34 and a carrier lifetime controlled valuable in a drift region. In a conduction state, both two IGBTs 33, 34 become conductive by applying a voltage not less than a threshold voltage to the gates 35, 36 of both two IGBTs 33, 34 and hence, a low ON voltage can be obtained.

Next, at the time of turning off the IGBT, by applying a voltage less than a threshold voltage prior to the gate 35 of the IGBT 33 at a low ON voltage, only the IGBT 34 at a high ON voltage is brought into a conduction state. By applying such a control, a state where the carrier concentration is low can be formed temporarily and, thereafter, a voltage less than a threshold voltage is applied to the IGBT 34 at a high ON voltage. Accordingly, a current generated due to discharging of carriers at the time of shifting the IGBT into a non-conduction state can be reduced.

An advantageous effect obtained from the technique formed of such configuration and control, is as follows. The carrier concentration in the vicinity of the collector region in the drift region, in this case, the average carrier concentration between the elements disposed in parallel can be controlled, and the average carrier concentration can be lowered temporarily by making only the IGBT 34 at a high ON voltage conductive and hence, a current at the time of turning off the IGBT can be reduced.

These double-gate-type IGBTs can suppress the generation of heat caused by an electric power loss thanks to a low loss performance. Accordingly, the increase of a maximum joining temperature when the element is operated can be suppressed. That is, a current that is allowable to flow into the element can be increased with respect to the maximum joining temperature that is allowable due to a joining lifetime of the element or the like and hence, a large increase of power capacity in the inverter can be realized with the same volume. On the other hand, the current density of the element can be increased and hence, the number of elements to be connected in parallel can be reduced whereby a value of miniaturization of a power conversion device can be also induced.

In this manner, the realization of a low electric power loss in an IGBT is an important factor that leads to the realization of a large capacitance and miniaturization of a power conversion device.

### CITATION LIST

### Patent Literature

Patent Literature 1: International Publication WO 2014/038064
Patent Literature 2: Japanese Unexamined Patent Application Publication No. 2012-238715

### SUMMARY OF INVENTION

### Technical Problem

To realize the large capacitance and the miniaturization of a power conversion device, it is necessary to enhance a turn-off cut-off resistance together with the realization of a lower electric power loss of an IGBT. The turn-off cut-off resistance is a maximum current that can be normally interrupted without breaking at the time of performing turn-off switching. For example, to realize a current that is 1.3 times as large as a rated current using an IGBT having a low electric power loss, it is necessary to increase a turn-off cut-off resistance also 1.3 times. The turn-off cut-off resistance is also referred to as reverse blocking safe operating area (RBSOA).

With respect to the double-gate-type IGBT structure described in the above-mentioned paten literatures 1 and 2, there is the description that the performance of a low electric power loss can be induced by controlling accumulated carriers using two gates. On the other hand, neither the patent literature 1 nor the patent literature 2 describes the turn-off cut-off resistance.

In general, a semiconductor chip (hereinafter simply referred to as “chip”) in which an IGBT is formed is constituted of: an active region; and a terminal region provided for attenuating an electric field and disposed on an outer periphery of the active region. The accumulated carriers in the IGBT are mainly accumulated in the active region where the gate is disposed. On the other hand, the diffusion of the cumulative carriers occurs in the lateral direction so that the cumulative carriers are also accumulated in the terminal region. The carriers accumulated in the terminal region are concentrated on the periphery of the active region at the time of turning-off the IGBT so that the current concentration is generated whereby local increase of electric power is generated thus giving rise to a possibility that the IGBT is broken. Particularly, this tendency is conspicuously confirmed in a high withstand IGBT that requires a chip using a thick wafer and a wide terminal region.

In the double-gate-type IGBT described in the patent literatures 1 and 2, a control of carriers in the active region is described. On the other hand, a control of carriers in a boundary between the active region and the terminal region is not described and hence, the improvement of the current concentration from the terminal region is difficult. Accordingly, the turn-off cut-off resistance cannot be enhanced in the double-gate-type IGBTs described in the patent literatures 1 and 2.

As has been described above, by adopting the structures described in the patent literature 1 and the patent literature 2, by controlling the carrier concentration between at the time of conduction and at the time of switching in the active region of the IGBT, the cumulative carrier concentration is optimized and hence, both a conduction loss and a turn-off loss can be lowered. On the other hand, the carrier control is difficult in the terminal region and the boundary between the active region and the terminal region and hence, the enhancement of a turn-off cut-off resistance is difficult whereby it is difficult to increase an allowable current capacity and a current density.

In view of the above, it is an object of the present invention to provide a highly reliable semiconductor device that possesses both a low conduction loss and a switching loss and, at the same time, can enhance a turn-off cut-off resistance, and a power conversion device that uses such a semiconductor device.

### Solution to Problem

To solve the above-mentioned problems, the present invention provides a semiconductor device that includes a switching gate and a carrier control gate that are independently driven from each other, and is characterized by including, in a state where the semiconductor device is viewed in a plan view, a central region cell, a peripheral region cell surrounding a whole circumference of the central region cell, and a terminal region surrounding a whole circumference of the peripheral region cell, in which the central region cell includes a switching element that has the switching gate and the carrier control gate, the peripheral region cell is disposed between the central region cell and the terminal region, and a gate of a switching element in the peripheral region cell is constituted of only the carrier control gate.

### Advantageous Effects of Invention

Accordingly, it is an object of the present invention to realize a highly reliable semiconductor device having both a low conduction loss and a low switching loss, and, at the same time, can enhance turn-off cut-off resistance, and a power conversion device that uses such a semiconductor device.

Accordingly, it is possible to realize the large increase of capacitance and the enhancement of reliability of a semiconductor device and a power conversion device that uses the semiconductor device.

Objects, configurations, and effects other than the above will be apparent from the description of the following embodiments.

### BRIEF DESCRIPTION OF DRAWINGS

FIG. 1 is a cross-sectional view of a semiconductor device according to a first embodiment of the present invention.

FIG. 2 is a drive circuit diagram that uses a semiconductor device illustrated in FIG. 1 and is a view that illustrates a drive signal.

FIG. 3 is a view conceptually illustrating a carrier distribution during a high conduction period of the semiconductor device illustrated in FIG. 1.

FIG. 4 is a view conceptually illustrating the carrier distribution during a low conduction period of the semiconductor device illustrated in FIG. 1.

FIG. 5 is a view conceptually illustrating the carrier distribution at the time of performing turn-off switching of the semiconductor device illustrated in FIG. 1.

FIG. 6 is a view conceptually illustrating the carrier distribution at the time of performing turn-off switching in a conventional semiconductor device.

FIG. 7 is a view illustrating a turn-off switching waveform and an electric power loss.

FIG. 8 is a view illustrating the correlation between a maximum rated voltage (MRV) and a turn-off cut-off resistance (STD).

FIG. 9 is a view illustrating the correlation between a switching loss (SL) and turn-off cut-off resistance (STD).

FIG. 10 is a plan layout view of a semiconductor device according to a second embodiment of the present invention.

FIG. 11 is a top plan view of a semiconductor chip according to the second embodiment of the present invention.

FIG. 12 is a plan layout view of an end portion of a gate in a longitudinal direction in the semiconductor device according to the second embodiment of the present invention.

FIG. 13 is a cross-sectional view taken along a line B-B′ in FIG. 12.

FIG. 14 is a view illustrating a modification of the structure illustrated in FIG. 12. (Modification 1)

FIG. 15 is a view illustrating a modification of the structure illustrated in FIG. 12. (Modification 2)

FIG. 16 is a plan layout view of a semiconductor device according to a third embodiment of the present invention.

FIG. 17 is a cross-sectional view taking along a line C-C′ in FIG. 16.

FIG. 18 is a view illustrating a profile distribution of accumulated carrier concentration in the semiconductor device illustrated in FIG. 16.

FIG. 19 is a cross-sectional view of a semiconductor device according to a fourth embodiment of the present invention.

FIG. 20 is a view illustrating a modification of the structure illustrated in FIG. 19. (Modification 3)

FIG. 21 is a view illustrating a profile distribution of accumulated carrier concentration in the semiconductor device illustrated in FIG. 19 and FIG. 20.

FIG. 22 is a plan layout view of a semiconductor device according to a fifth embodiment of the present invention.

FIG. 23 is a plan layout view of a semiconductor device according to a sixth embodiment of the present invention.

FIG. 24 is a cross-sectional view of a semiconductor device according to a seventh embodiment of the present invention.

FIG. 25 is a view illustrating the circuit configuration of a typical power conversion device.

FIG. 26 is a cross-sectional view of a semiconductor device to which a prior art described in the patent literature 1 is applied.

FIG. 27 is a circuit diagram of a semiconductor device to which a prior art described in the patent literature 2 is applied.

### DESCRIPTION OF EMBODIMENTS

Hereinafter, embodiments of the present invention are described with reference to drawings. In the respective drawings, identical configurations are given with the same symbols, and the detailed description of overlapping portions is omitted.

In the drawing, the expressions n-, n indicate that a semiconductor layer is an n type, and also indicate that impurity concentration of n is relatively higher than impurity concentration of n-. Further, the expressions p-, p indicate that a semiconductor layer is a p type, and also indicate that impurity concentration of p is relatively higher than impurity concentration of p-.

Hereinafter, an IGBT having two gates is referred to as a double gate type IGBT. However, such an IGBT is also referred to as a dual gate type IGBT. Both IGBTs have same definition.

### First Embodiment

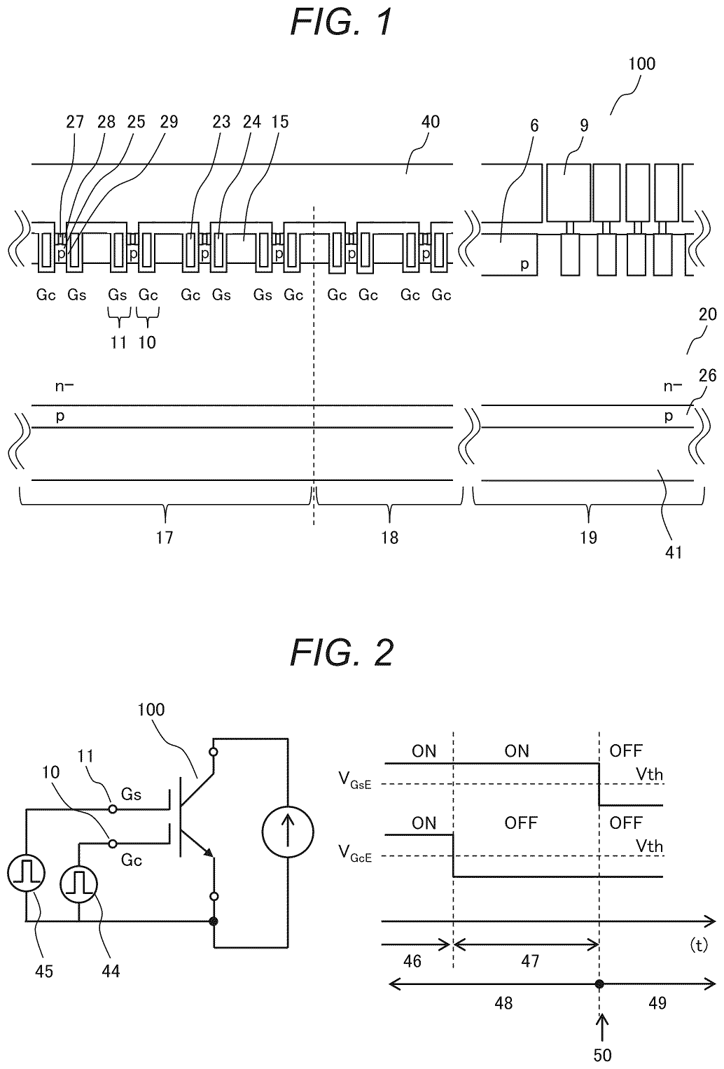

An insulation gate type (gate control type) semiconductor device according to a first embodiment of the present invention is described with reference to FIG. 1 to FIG. 9. FIG. 1 is a cross-sectional view of the semiconductor device 100 according to this embodiment.

The semiconductor device 100 according to this embodiment is a double-gate-type IGBT having a plurality of trench gate shapes. A central region 17, a peripheral region 18 and a terminal region 19 are formed on a common n-type drift layer 20. The central region 17 and the peripheral region 18 are regions where carriers are injected into the n-type drift layer 20 using a gate bias when the IGBT is in a conduction state. On the other hand, the terminal region 19 is a region for attenuating an electric field with respect to a high voltage applied when the IGBT is in a non-conduction state.

At an upper portion of the central region 17, switching elements including a switching gate (Gs) 11 having a trench shape and a carrier control gate (Gc) 10 as gates are disposed. On the other hand, above the peripheral region 18, switching elements that the switching gates (Gs) 11 do not exist as the gates, and the gates are constituted of only the carrier control gates (Gc) 10 are disposed.

Further, the semiconductor device 100 includes: p type well layers 25 that are disposed adjacently to an n-type drift layer 20 in a vertical direction; and a p type collector layer 26 that is disposed adjacently to the n-type drift layer 20 in the vertical direction on a side opposite to the p type well layers 25.

Further, above the p type well layers 25, p type electricity supply layers 27 and n type emitter layers 28 are disposed adjacently to each other. These p type well layers 25 and the n type emitter layers 28 are in contact with switching gate (Gs) electrodes 24 that form first gate electrodes having a trench gate shape and carrier control gate (Gc) electrodes 23 that form second gate electrodes having a trench gate shape in the same manner via the gate insulation film (gate oxide film) 29.

In such a configuration, the switching gate (Gs) 11 is constituted of: the gate insulation films 29 that are in contact with the n type emitter layers 28 and the p type well layers 25; and switching gate (Gs) electrodes 24 provided in a state where the switching gate (Gs) electrodes 24 face and are in contact with the gate insulation films 29. The carrier control gate (Gc) 10 is constituted of: the gate insulation films 29 that are in contact with n type emitter layers 28 and the p type well layers 25; and the carrier control gate (Gc) electrodes 23 provided in a state that the carrier control gate (Gc) electrodes 23 face and are in contact with the gate insulation films 29. These switching gates (Gs) 11 and carrier control gates (Gc) 10 are collectively referred to as “trench gates” hereinafter.

An emitter electrode 40 has a trench shape protruding downward, and is in contact with the p type electricity supply layers 27 and the n type emitter layers 28. The respective trench gates are insulated from each other via the gate insulation film 29. The n-type drift layer 20 is disposed adjacently to the p type collector layer 26 on a surface thereof on an opposite pole side with respect to the p type well layers 25. The semiconductor device 100 further includes a collector electrode 41 that is in contact with the p type collector layer 26.

The terminal region 19 includes, above the n-type drift layer 20, a p type high concentration layers 6 and floating electrodes 9 that are disposed in intermittently. With such a structure, when a high voltage is applied between the collector electrode 41 and the emitter electrode 40, equipotential lines are disposed at a fixed interval and hence, it is possible to prevent an avalanche breakdown caused by electric field concentration.

The terminal region 19 is also referred to as guard ring, termination or the like in general.

The p type high concentration layers 6 may not be disposed intermittently but may be continuously disposed with a concentration gradient. Further, the semiconductor device 100 adopts the structure where the floating electrodes 9 are not disposed, and the present invention is not limited to the specific structure with respect to the terminal region.

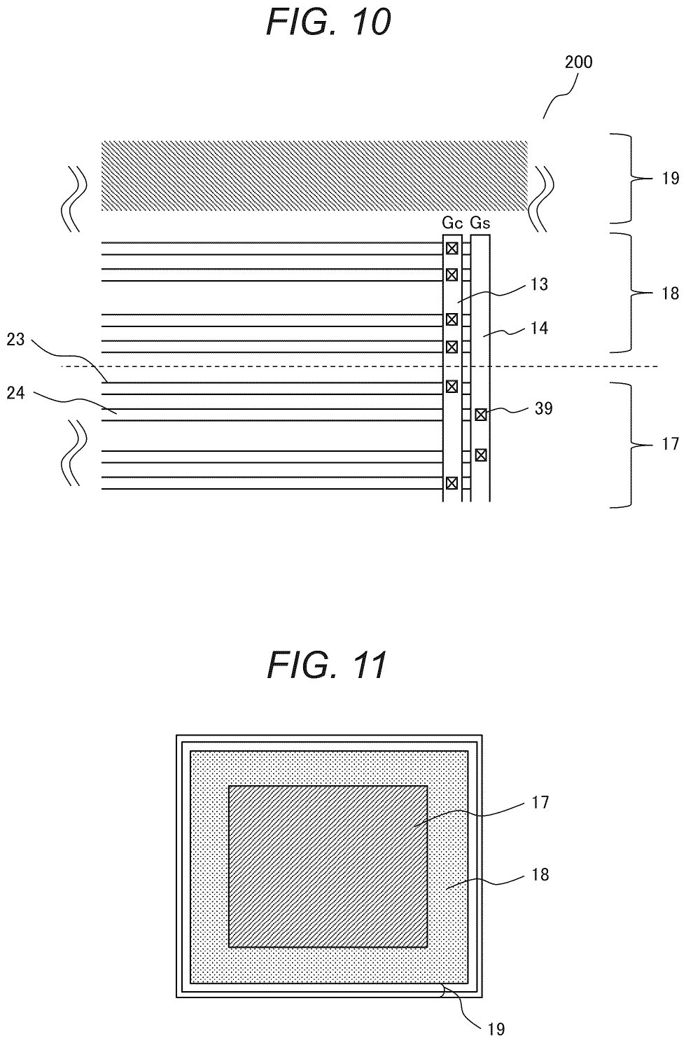

In the semiconductor device 100, the n-type drift layer 20, the emitter electrode 40 and the collector electrode 41 are shared in common by the central region 17, the peripheral region 18 and the terminal region 19, and, as described later with reference to FIG. 11, these components are constituted in the inside of a one-chip semiconductor element.

The peripheral region 18 is disposed so as to surround the whole circumference of the central region 17, and the terminal region 19 is disposed so as to surround the whole circumference of the peripheral region 18. That is, the peripheral region 18 is a region that is sandwiched by the central region 17 and the terminal region 19 (FIG. 11). As described above, both the switching gates (Gs) 11 and the carrier control gates (Gc) 10 are disposed in the central region 17, and only the carrier control gates (Gc) 10 are disposed in the peripheral region 18. This configuration is provided for enabling the semiconductor device 100 to exhibit an effect of reducing carrier concentration during a carrier extraction period as described below.

A semiconductor substrate used in this embodiment is formed using silicon (Si), or silicon carbide (SiC), for example. The gate insulation film 29 used in this embodiment is formed using silicon dioxide (SiO₂), for example.

Next, an operation of the semiconductor device 100 according to this embodiment is described with reference to FIG. 2 to FIG. 6.

FIG. 2 illustrates a drive circuit diagram that uses the semiconductor device 100 of this embodiment and drive signals.

The semiconductor device 100 of this embodiment exhibits a highly reliable operation with a low loss and a high turn-off cut-off resistance with use of drive signals generated by gate drivers 44, 45 that respectively drive the carrier control gates (Gc) 10 and the switching gates (Gs) 11.

Symbol 48 in the drawing on a right side of FIG. 2 indicates a conduction period of an IGBT, and symbol 49 indicates a non-conduction period.

First, in the IGBT conduction period, a high conduction period 46 and a low conduction period 47 are set. In the high conduction period 46, a voltage not less than a threshold voltage (Vth) that forms an inversion layer in the p type well layers 25 of the IGBT is applied to the carrier control gates (Gc) 10 and the switching gates (Gs) 11. In the low conduction period 47, a voltage less than the threshold voltage is applied to the carrier control gates (Gc) 10, and a voltage not less than the threshold voltage is applied to the switching gates (Gs) 11.

In the high conduction period 46, accumulated carrier concentration in the IGBT is increased and hence, a low ON voltage performance is induced. In the low conduction period 47, accumulated carrier concentration in the IGBT is reduced, and subsequently, in the non-conduction period 49, when the IGBT is turned off by applying a voltage less than the threshold voltage to the switching gates (Gs) 11, a reverse prevention voltage is applied to the IGBT at a high speed and, further, a current is reduced at a high speed and hence, it is possible to realize turn-off switching 50 that can secure a low loss and a high turn-off cut-off resistance.

That is, by driving the IGBT structure of this embodiment illustrated in the drawing on a left side in FIG. 2 using drive signals illustrated in the drawing on a right side in FIG. 2, the semiconductor device 100 can induce an IGBT performance that can secure a low loss and high turn-off cut-off resistance.

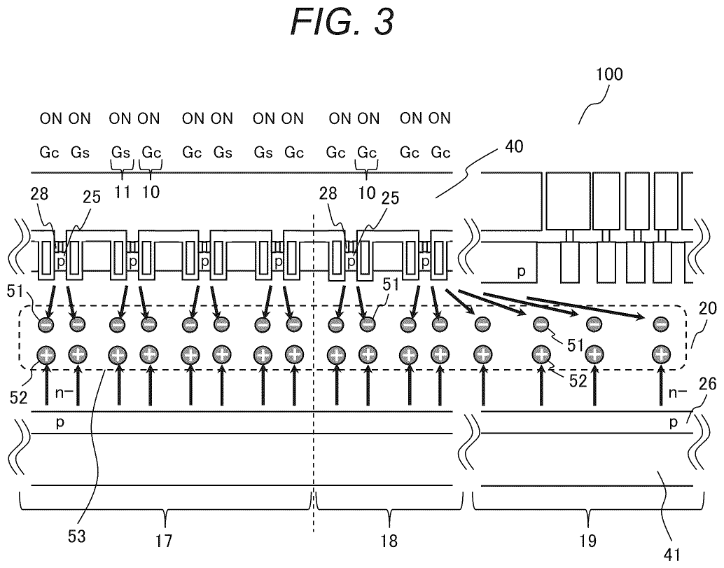

FIG. 3 illustrates the carrier distribution in the semiconductor device 100 of this embodiment in the high conduction period 46. FIG. 3 illustrates the distribution of carriers formed of electrons 51 and the holes 52 when a positive voltage of not less than a threshold voltage for generating an electron layer that is an inversion layer in the p type well layers 25 is applied to the carrier control gates (Gc) 10 and the switching gates (Gs) 11 and, further, a forward voltage that passes through the IGBT is applied between the collector electrode 41 and the emitter electrode 40.

The electrons 51 are injected into the n-type drift layer 20 from the n type emitter layers 28 via the electron layer formed in the p type well layers 25 from the emitter electrode 40. Then, by being induced by the electrons 51 injected into the n-type drift layer 20, the holes 52 are injected into the n-type drift layer 20 from the p type collector layer 26 and hence, the electric conductivity modulation 53 is generated in the n-type drift layer 20.

In this embodiment, the semiconductor device 100 includes the central region 17 and the peripheral region 18. Further, electrons 51 are injected from the n type emitter layers 28 that are disposed adjacently to the carrier control gates (Gc) 10 and the switching gates (Gs) 11 disposed in the central region 17 and the carrier control gates (Gc) 10 disposed in the peripheral region 18 respectively, the carrier concentration accumulated by the electric conductivity modulation 53 can be enhanced.

Further, the electrons 51 injected into the peripheral region 18 are diffused also into the terminal region 19 and hence, the injection of the holes 52 is also induced from the p type collector layer 26 disposed below the terminal region 19 and hence, the carrier concentration accumulated by the electric conductivity modulation 53 is increased also in the terminal region 19.

Accordingly, in the semiconductor device 100 of this embodiment, it is possible to allow a predetermined current to flow with a low voltage drop, that is, at a low ON voltage and hence, performance with a low loss at the time of conduction can be induced.

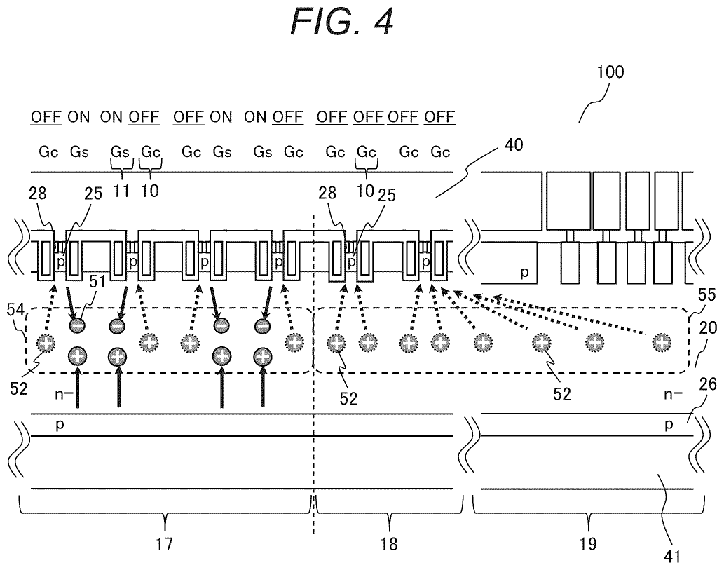

FIG. 4 illustrates the carrier distribution in the semiconductor device 100 of this embodiment during the low conduction period 47 where a negative voltage of less than a threshold voltage is applied to the carrier control gates (Gc) 10 after the high conduction period 46.

In a state where a forward voltage that passes through the IGBT is applied between the collector electrode 41 and the emitter electrode 40, an accumulation layer is formed in the p type well layers 25 that are in contact with the carrier control gates (Gc) 10, and the holes 52 that contribute to the electric conductivity modulation in the inside of the n-type drift layer 20 are discharged to the emitter electrode 40 via the accumulation layer.

In the semiconductor device 100 of this embodiment, the holes 52 in the central region 17 and the peripheral region 18 are discharged by the carrier control gates (Gc) 10 and, at the same time, the holes 52 that are accumulated also in the terminal region 19 are discharged into the emitter electrode 40 via the accumulation layer formed in the p type well layers 25 in the peripheral region 18 by a positive bias of the carrier control gates (Gc) 10 in the peripheral region 18.

Further, in this embodiment, the semiconductor device 100 adopts the switching element where the switching gates (Gs) 11 do not exist as the gates and the gates are formed of only the carrier control gates (Gc) 10 in the peripheral 18. Accordingly, the electrons 51 are not injected into the switching gates (Gs) 11 in the peripheral region 18 unlike the central region 17.

Accordingly, a profile 54 of accumulated carriers temporarily having a low concentration can be formed in the n-type drift layer 20 in the central region 17 and, at the same time, a profile 55 of accumulated carriers having extremely low concentration can be formed in the n-type drift layer 20 in the peripheral region 18 and the terminal region 19. That is, in a case where the IGBT is in a conduction state, a state can be formed where a current flows only in the central region 17.

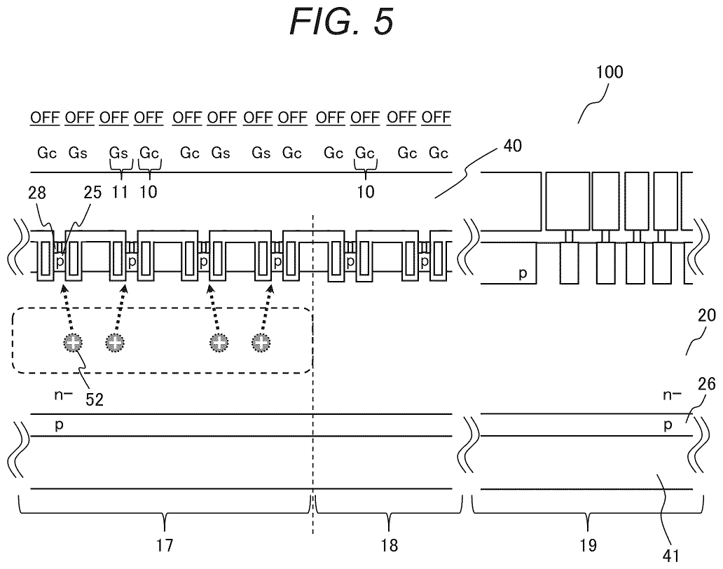

FIG. 5 illustrates the carrier distribution in the semiconductor device 100 of this embodiment at a turn-off switching time 50 at which a negative voltage of less than a threshold voltage is applied to the switching gate (Gs) 11 after the low conduction period 47.

When an off bias is applied to the switching gate (Gs) 11 so that the operation of the semiconductor device 100 is shifted to a turn-off switching operation at which the semiconductor device 100 transitions from a conduction state to a non-conduction state after the low conduction period 47, since the concentration of carriers accumulated in the n-type drift layer 20 is low, the holes 52 are discharged to the emitter electrode 40 at a high speed and the electrons 51 are discharged to the collector electrode 41 at a high speed. Accordingly, a reverse flow blocking voltage is applied to the IGBT at a high speed and, at the same time, a current is decreased at a high speed and hence, turn-off switching having a low loss is realized.

In the semiconductor device 100 of this embodiment, in the low conduction period 47 immediately before the turn-off switching, a state (a profile 55) where the carrier concentration is accumulated in the peripheral region 18 and the terminal region 19 at an extremely low concentration is formed. Accordingly, a current at the turn-off switching time minimally flows into the region of the profile 55 and hence, the flow of the current is limited to only the central region 17. That is, a current generated by the holes 52 that flow into the emitter electrode 40 does not flow into the peripheral region 18 in a concentrated manner. Accordingly, the generation of electric power caused by the local concentration of the current and the increase of a temperature brought about by such generation of the current can be suppressed and hence, it is possible to increase the turn-off cut-off resistance that is defined as a current value at which the current can be cut off without causing breaking after the current is supplied.

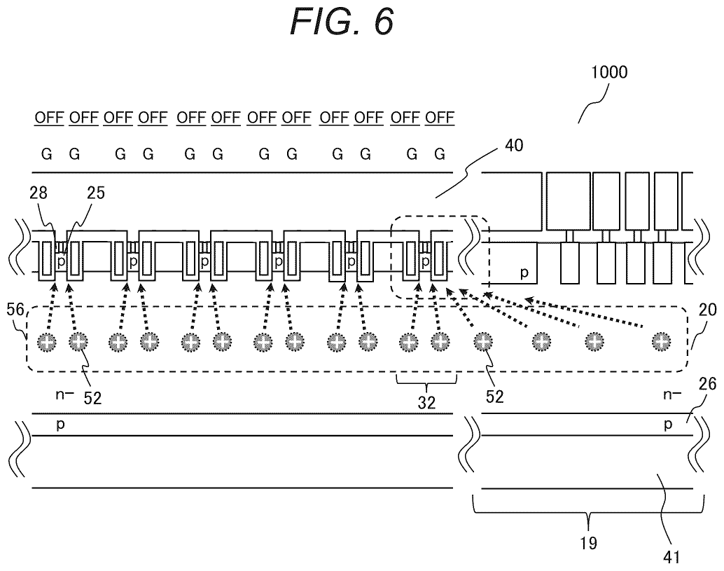

FIG. 6 illustrates the distribution of carriers at the turn-off switching time of a conventional semiconductor device (IGBT) 1000 that is illustrated as a comparison example for facilitating the understanding of the present invention. Holes 52 of high concentration accumulated when the semiconductor device 100 is in a conduction state are discharged to the emitter electrode 40, an operation of the semiconductor device becomes an operation where a current is decreased at a low speed and hence, a large turn-off switching loss occurs. Further, the holes 52 that are accumulated in the terminal region 19 when the semiconductor device 100 is in a conduction state are intensively discharged to the emitter electrode 40 of a cell 32 disposed on a boundary with the terminal region 19. Accordingly, a current density of the cell 32 is increased thus giving rise to breaking due to the generation of electric power caused by the local current concentration and the temperature elevation brought about by the local current concentration. That is, the turn-off cut-off resistance is restricted by the breakdown strength of the cell 32.

In view of the above, in the semiconductor device 100 of this embodiment, the concentration of the accumulated carriers in the IGBT can be controlled by a gate bias of the carrier control gate (Gc) 10. Particularly, the controllability of accumulated carrier concentration in the peripheral region 18 and the terminal region 19 can be increased. Accordingly, it is possible to realize the highly reliable IGBT that possesses both a low ON voltage performance and a low turn-off loss performance when the semiconductor device is in a conduction state and secures a high turn-off cut-off resistance.

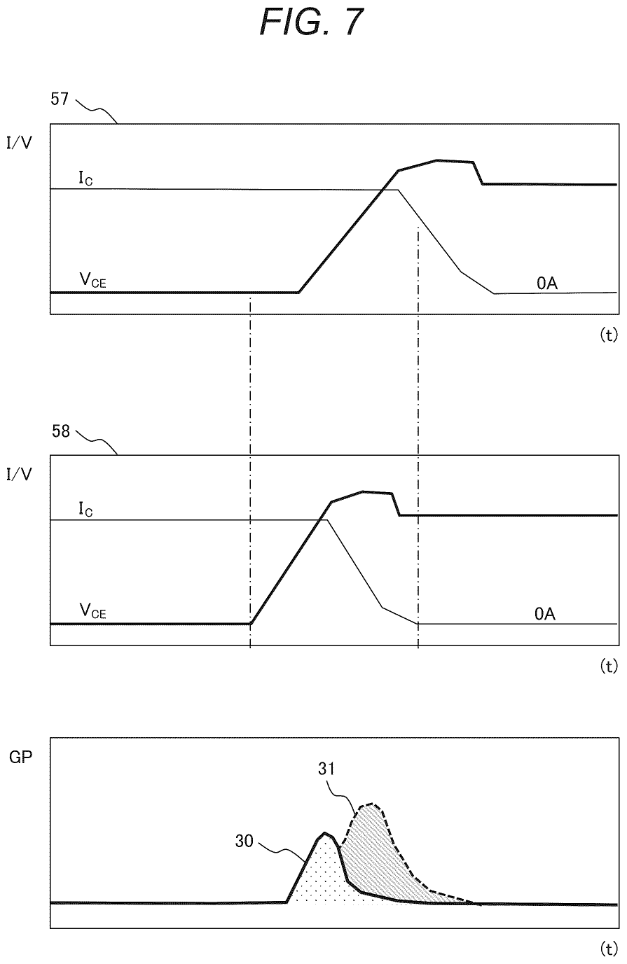

Next, advantageous effects of the present invention relating to the turn-off cut-off resistance is described with reference to FIG. 7 to FIG. 9.

FIG. 7 illustrates a comparison between a turn-off switching waveform 58 of the double gate type IGBT according to the present invention and a turn-off switching waveform 57 of a conventional double gate type IGBT based on the patent literature 1.

In this comparison, the waveforms in a state where a large current of not less than a rated current that is a use condition of a power conversion device flows are compared to each other.

By applying an off bias to the switching gate (Gs) 11, the IGBT transitions from a conduction state to a non-conduction state. FIG. 7 illustrates a change in a collector current I_{C} and a change in a collector-emitter voltage V_{CE} during such transitioning, or a generated electric power GP that is a product of the I_{C} and the V_{CE}.

When an off bias is applied to the switching gate (Gs) 11, carriers in the inside of the IGBT are discharged so that the V_{CE} is increased first. In such an operation, in the double gate type IGBT 58 according to the present invention, the carrier concentration in the peripheral region 18 and the terminal region 19 during the low conduction period 47 immediately before the transitioning is low and hence, compared to the conventional double gate type IGBT 57, the V_{CE} is increased to a power source voltage at a high speed. This phenomenon is, mainly, an effect that the carrier concentration in the drift region in the vicinity of the emitter region, that is, the carrier concentration in the drift region closer to the surface of the IGBT is reduced by the present invention.

Next, when the V_{CE} reaches a power source voltage, the decreasing of the I_{C} starts. In the double gate type IGBT 58 according to the present invention, during the low conduction period 47, the carrier concentration in the peripheral region 18 and the terminal region 19 is low, particularly, the carrier concentration in the drift region in the vicinity of the collector region, that is, the carrier concentration in the drift region closer to the back surface of the IGBT is low. Accordingly, the collector current I_{C} is lowered at a high speed, or reaches OA with a small tail period and transitions to a non-conduction state. That is, according to the double gate type IGBT 58 of the present invention, both the collector-emitter voltage V_{CE} and the collector current I_{C} can be changed at a high speed compared to the conventional double gate type IGBT 57.

By integrating generated powers GP brought about by a change in V_{CE}, I_{C}, a current loss at the time of turn off switching can be calculated. As illustrated in FIG. 7, it is understood that, according to the double gate type IGBT 58 of the present invention, change periods of the V_{CE}, I_{C} are short and hence, a generated electric power loss 30 is smaller than a conventional electric power loss 31.

The point that makes the present invention different from the conventional double gate type IGBT is as follows. In the prior art, also in the peripheral region 18, the switching element that includes the switching gate (Gs) 11 and the carrier control gate (Gc) 10 as the gate is used. On the other hand, the present invention uses the switching element where the switching gate (Gs) 11 does not exist in the peripheral region 18 as the gate so that the switching element is constituted of only the carrier control gate (Gc) 10. That is, according to the present invention, it is possible to suppress the local current concentration in the peripheral region 18 and hence, the local electric power loss can be reduced and the temperature elevation can be suppressed. Accordingly, the turn-off cut-off resistance can be enhanced.

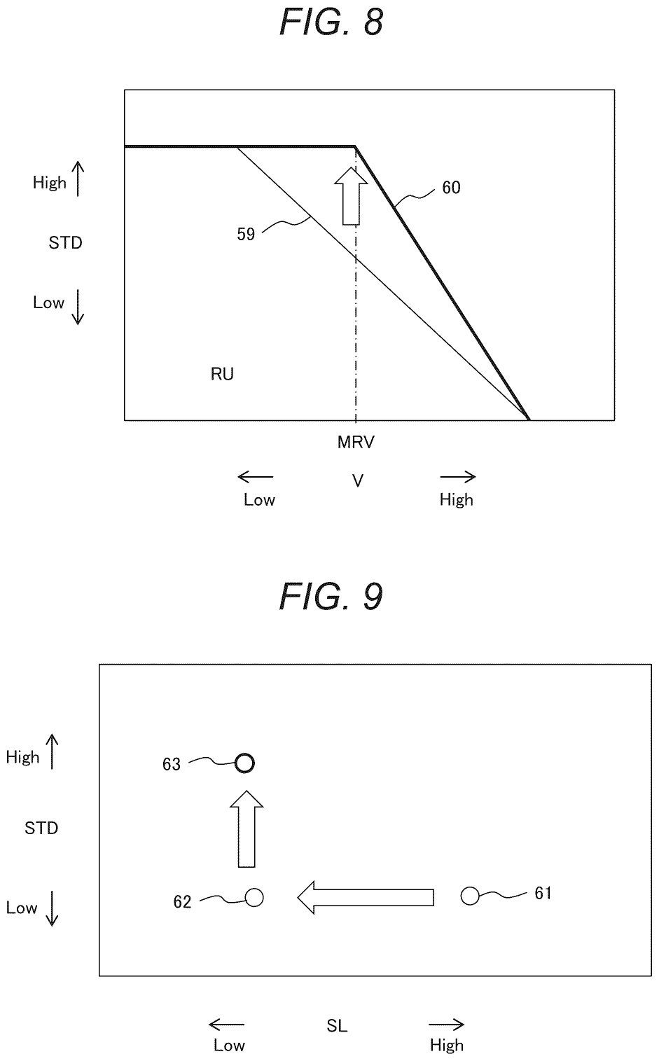

FIG. 8 illustrates the correlation between a turn-off cut-off resistance STD and the voltage V with respect to the double gate type IGBT according to the present invention and the conventional double gate type IGBT. MRV indicates a maximum rated voltage, symbol 59 indicates a turn-off cut-off resistance of the conventional double gate type IGBT, and symbol 60 indicates a turn-off cut-off resistance of the double gate type IGBT according to the present invention.

In the graph illustrated in FIG. 8, a region disposed inside a correlation line indicates a safe operation region (a range of use: RU) where it is possible to issue a command of permitting the use of the power conversion device without causing breaking in turn-off switching. According to the present invention, the use range RU can be expanded and hence, a breakdown strength can be enhanced under a switching condition of a high voltage and a large current whereby it is possible to provide a design permission condition of a power conversion device that conforms to larger electric power.

FIG. 9 illustrates correlation between a switching loss SL and a turn-off cut-off resistance STD between the IGBT of the present invention, conventional double gate type IGBTs 63, 62, and a conventional (single gate type) IGBT 61 formed of one kind of gate.

In the graph illustrated in FIG. 9, a switching loss SL indicates a performance at a rated voltage used in a normal operation of a power conversion device, and a turn-off cut-off resistance STD indicates a performance at a maximum rated voltage to be guaranteed instantaneously. With respect to the relationship between a rated voltage and a maximum rated voltage, there exists the relationship of rated voltage <maximum rated voltage. Compared to the conventional IGBT 61 formed of one kind of gate, in the conventional double gate type IGBT 62, carriers are dynamically controlled and hence, a switching loss SL can be reduced. On the other hand, because of a breakdown strength of the peripheral region 18, it is difficult to increase a turn-off cut-off resistance STD.

By adopting the double gate type IGBT 63 according to the present invention, it is possible to induce both a switching loss SL substantially equal to or less than a switching loss SL of the conventional double gate type IGBT 62 and a turn-off cut-off resistance STD higher than a turn-off cut-off resistance of the conventional double gate type IGBT 62. That is, it is possible to provide the double gate type IGBT that possesses both a low switching loss and a high output.

As has been described heretofore, the semiconductor device 100 (the double gate type IGBT) of this embodiment includes the switching gate (Gs) electrodes 24 and the carrier control gate (Gc) electrodes 23 that are independently driven from each other, and is characterized by including, in a state where the semiconductor device 100 is viewed in a plan view, the central region (cell) 17, the peripheral region (cell) 18 surrounding the whole circumference of the central region (cell) 17, and the terminal region 19 surrounding the whole circumference of the peripheral region (cell) 18, in which the central region (cell) 17 includes the switching element that has the switching gate (Gs) and the carrier control gate (Gc), the peripheral region (cell) 18 is disposed between the central region (cell) 17 and the terminal region 19, and the gate of the switching element in the peripheral region (cell) 18 is constituted of only the carrier control gate (Gc) electrodes 23.

According to the semiconductor device 100 (the double gate type IGBT) of this embodiment, it is possible to realize the highly reliable IGBT capable of conforming to large electric power having low loss performance to combine a low conduction loss and a low turn-off loss, and a high turn-off cut-off resistance.

### Second Embodiment

A semiconductor device of an insulation gate type (gate control type) according to a second embodiment of the present invention is described with reference to FIG. 10 to FIG. 15. FIG. 10 is a plan layout view of a semiconductor device 200 according to this embodiment, and illustrates gates extending in a longitudinal direction. FIG. 11 is a top plan view of a chip on which the semiconductor device 200 illustrated in FIG. 10 is mounted. The chip illustrated in FIG. 11 has the configuration shared in common by all embodiments including the first embodiment and succeeding embodiments.

In the semiconductor device 200 according to this embodiment, as illustrated in FIG. 10 and FIG. 11, a peripheral region 18 is disposed inside a terminal region 19 that is disposed on a periphery of the chip, and a central region 17 is disposed inside the peripheral region 18. Gate electrodes of trench gates of an IGBT that are disposed at the central region 17 are constituted of switching gate (Gs) electrodes 24 and carrier control gates (Gc) electrodes 23. Gate electrodes of the trench gates of the IGBT that are disposed at the peripheral region 18 are constituted of only the carrier control gates (Gc) electrodes 23.

The central region 17 and the peripheral region 18 are, for example, formed in a divided manner using masks through the common manufacturing steps, for example.

In the semiconductor device 200, the plurality of switching gate (Gs) electrodes 24 and the plurality of carrier control gate (Gc) electrodes 23 are respectively connected as a bundle to a switching gate (Gs) wiring 14 and a carrier control gate (Gc) wiring 13 via contact layers 39. Accordingly, the IGBT of this embodiment is operated using two gate signals.

In the semiconductor device 200, although four carrier control gate (Gc) electrodes 23 are illustrated as the carrier control gate (Gc) electrodes 23 in the peripheral region 18, the number of the carrier control gate (Gc) electrodes 23 is not limited to four. The higher a withstand voltage of the element, the larger an area of the terminal region 19 for attenuating an electric field becomes, and a thickness of a drift layer becomes large and hence, conductivity modulation of the terminal region 19 during a high conduction period 46 is enhanced. Accordingly, an advantageous effect of the present invention is exhibited by sufficiently extracting carriers during a low conduction period 47 and hence, it is effective to make the peripheral region 18 wide and to increase the number of the carrier control gates (Gc) electrodes 23.

In FIG. 10, the switching gate (Gs) wiring 14 and the carrier control gate (Gc) wiring 13 are configured to extend only on the peripheral region 18 and the central region 17. However, for the purpose of reducing a wiring resistance or for the purpose of facilitating the supply of electricity, such wirings may be provided to the terminal region 19.

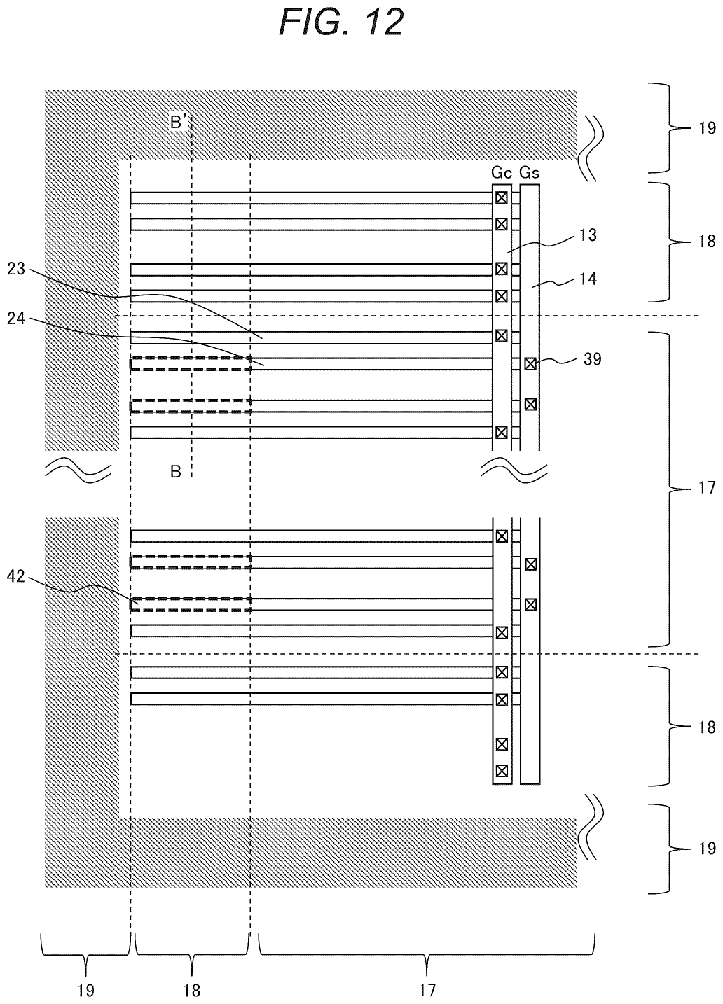

FIG. 12 illustrates a plan layout view of longitudinal direction end portions of the gates in the semiconductor device 200 according to the present invention. Also in the longitudinal direction end portion of the gate, the terminal region 19 is disposed for the purpose of attenuating an electric field for realizing a high withstand voltage. Carriers are also accumulated in the terminal region 19, in this embodiment, the peripheral region 18 is disposed between the central region 17 and the terminal region 19.

In the semiconductor device 200, in the peripheral region 18 in the longitudinal direction of the gates, the switching gate (Gs) electrodes 24 extend from the central region 17, and a dummy gate region 42 (a dummy region where the gates do not function as the switching gates (Gs)) that is not arranged adjacently to the n type emitter layer 28 is disposed. The dummy gate region 42 is a region where the n type emitter layer 28 that is disposed so as to face the switching gates (Gs) electrodes 24 by way of a gate insulation film is not formed. That is, electrons 51 are not injected during the low conduction period 47. That is, also in the peripheral region 18 at the longitudinal direction end portions of the gates, as the gate electrodes of the trench gates having the n type emitter layers 28, only the carrier control gate (Gc) electrodes 23 are disposed.

During the low conduction period 47, the holes 52 are discharged by the carrier control gate (Gc) electrodes 23 in the peripheral region 18 at the longitudinal direction end portions of the gates. Accordingly, at the turn off switching time, the current concentration to the peripheral region 18 can be suppressed in the longitudinal direction of the gates and hence, a high turn-off cut-off resistance can be acquired.

In FIG. 12, the switching gate (Gs) wiring 14 and the carrier control gate (Gc) wiring 13 are configured to extend only on the peripheral region 18 and the central region 17. However, for the purpose of reducing a wiring resistance or for the purpose of facilitating the supply of electricity, such wirings may be provided to the terminal region 19.

FIG. 13 illustrates a cross section taken along a line B-B′ in FIG. 12. The terminal region 19 is disposed outside the peripheral region 18. In the peripheral region 18 on the cross section, in the switching gate (Gs) electrodes 24, the n type emitter layers 28 that are disposed so as to face the switching gate (Gs) electrodes 24 do not exist, and the dummy gate region 42 is disposed.

That is, when the semiconductor device 200 is viewed in a plan view, the gate electrodes of the switching gate (Gs) electrodes 24 are disposed in an extending manner also in the peripheral region 18, the gate electrodes disposed in the peripheral region 18 are dummy gates on which the n type emitter layers 28 are not disposed by way of the gate insulation films 29.

By the carrier control gates (Gc) electrodes 23 that are disposed in the peripheral region 18, the carriers that are accumulated in the n-type drift layer 20 during the high conduction period 46 by conductivity modulation can be extracted during the low conduction period 47. Accordingly, at the time of performing turn-off switching, a breakdown strength due to current concentration in the peripheral region 18 can be enhanced whereby a high turn-off cut-off resistance can be acquired.

### Modification 1

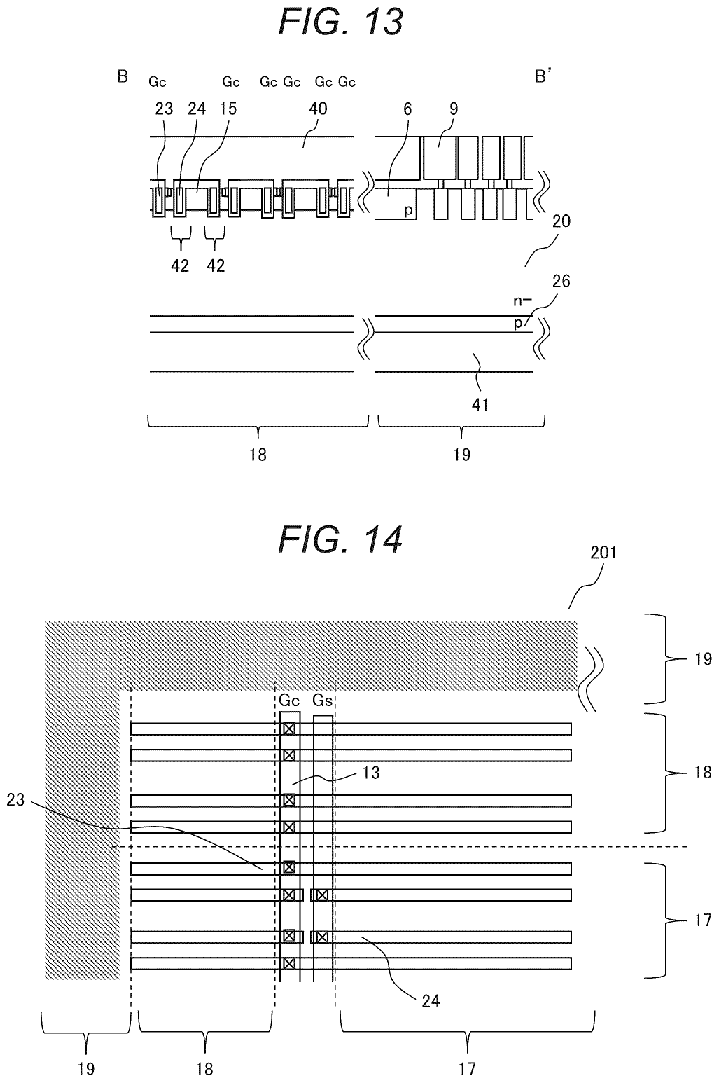

FIG. 14 illustrates a modification of the semiconductor device 200 illustrated in FIG. 12.

In the modification illustrated in FIG. 14, in the longitudinal direction of the gates, the central region 17 and the peripheral region 18 are divided by carrier control gate (Gc) wiring 13, the switching gate (Gs) wiring 14 and the contact layer 39, and in the peripheral region 18 on an end portion side in the longitudinal direction of the gates, the gate electrodes are constituted of only the carrier control gate (Gc) electrodes 23.

### Modification 2

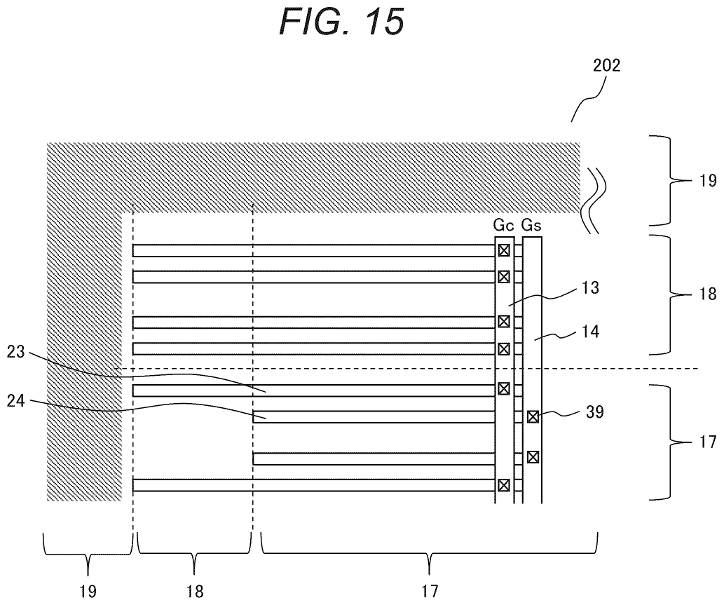

FIG. 15 illustrates another modification of the semiconductor device 200 illustrated in FIG. 12.

In the modification illustrated in FIG. 15, by adopting the layout where the switching gate (Gs) electrodes 24 do not exist in the peripheral region 18 in the longitudinal direction of the gates, the gate electrodes of the trench gates in the peripheral region 18 are constituted of only the carrier control gate (Gc) electrodes 23.

By adopting the configuration illustrated in FIG. 14 (modification 1) and the configuration illustrated in FIG. 15 (modification 2), in the low conduction period 47, the holes 52 are discharged by the carrier control gate (Gc) electrodes 23 in the peripheral region 18 and hence, the current concentration toward the peripheral region 18 can be suppressed also in the longitudinal direction of the gates at the time of performing the turn-off switching whereby a high turn-off cut-off resistance can be acquired.

In FIG. 14 and FIG. 15, the switching gate (Gs) wiring 14 and the carrier control gate (Gc) wiring 13 are configured to extend only on the peripheral region 18 and the central region 17. However, for the purpose of reducing a wiring resistance or for the purpose of facilitating the supply of electricity, such wirings may be provided to the terminal region 19.

### Third Embodiment

A semiconductor device of an insulation gate type (gate control type) according to a third embodiment of the present invention is described with reference to FIG. 16 to FIG. 18. FIG. 16 is a plan layout view of a semiconductor device 300 according to this embodiment, and illustrates gates extending in a longitudinal direction.

As illustrated in FIG. 16, the semiconductor device 300 according to this embodiment adopts the following layout. Assuming a center distance between emitter regions disposed adjacently to each other in the central region 17 as a and a center distance between the emitter regions disposed adjacently in the peripheral region 18 as b, the relationship of b≤a is established, and more preferably, the relationship of b<a is established.

By establishing such a relationship in the semiconductor device 300, the conductivity modulation in the peripheral region 18 can be suppressed during the high conduction period 46, and an area of the carrier control gate (Gc) electrodes 23 that effects the extraction of hole carriers 52 during the low conduction period 47 can be increased and hence, a breakdown strength in the peripheral region 18 at the time of performing turn-off switching can be further enhanced.

In the semiconductor device 300, although six carrier control gate (Gc) electrodes 23 are illustrated as the carrier control gate (Gc) electrodes 23 in the peripheral region 18, the number of the carrier control gate (Gc) electrodes 23 is not limited to six. The higher a withstand voltage of the element, the larger an area of the terminal region 19 for attenuating an electric field becomes, and a thickness of a drift layer becomes large and hence, conductivity modulation of the terminal region 19 during a high conduction period 46 is enhanced. Accordingly, an advantageous effect of the present invention is exhibited by sufficiently extracting carriers during a low conduction period 47 and hence, it is effective to make the peripheral region 18 wide and to increase the number of the carrier control gate (Gc) electrodes 23.

Also in FIG. 16, the switching gate (Gs) wiring 14 and the carrier control gate (Gc) wiring 13 are configured to extend only on the peripheral region 18 and the central region 17. However, for the purpose of reducing a wiring resistance or for the purpose of facilitating the supply of electricity, such wirings may be provided to the terminal region 19.

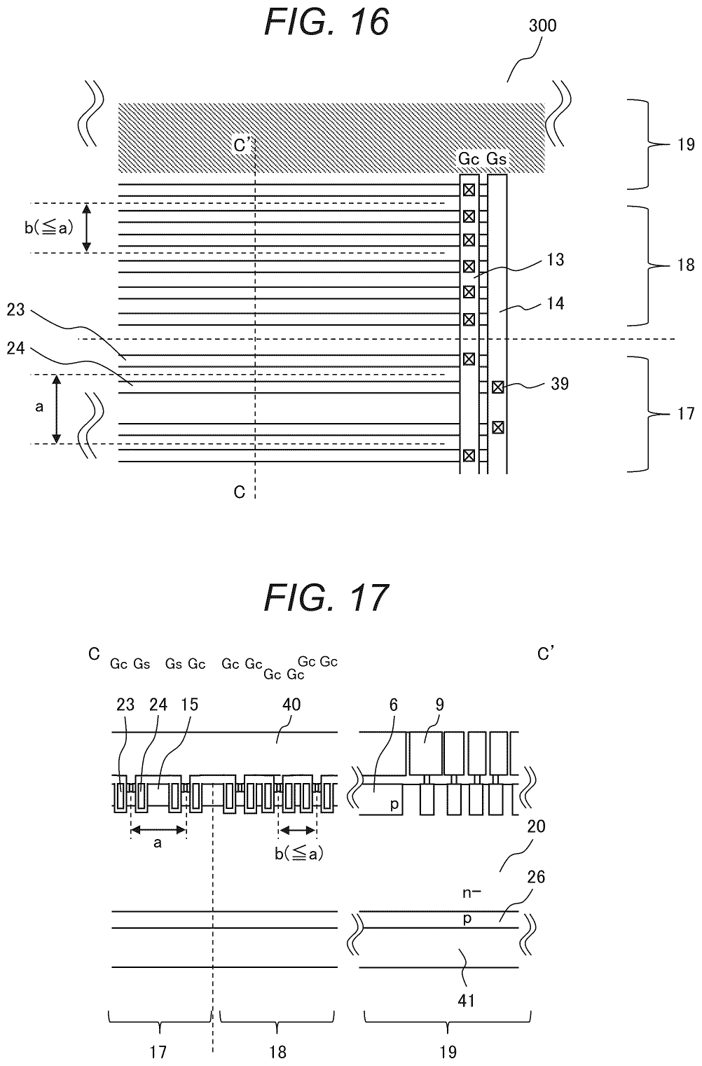

FIG. 17 illustrates a cross section taken along a line C-C′ in FIG. 16. The peripheral region 18 is disposed outside the center region 17, and the terminal region 19 is disposed outside the peripheral region 18. Further, the above-mentioned relationship b≤a, more preferably b<a is established in the semiconductor device 300 and hence, the semiconductor device 300 is configured such that the density of the carrier control gate (Gc) electrodes 23 in the peripheral region 18 becomes high compared to the density of the carrier control gate (Gc) electrodes 23 in the central region 17.

By the carrier control gates (Gc) electrodes 23 that are disposed in the peripheral region 18 at high density, the carriers that are accumulated in the n-type drift layer 20 in the peripheral region 18 and the terminal region 19 during the high conduction period 46 by conductivity modulation can be efficiently extracted during the low conduction period 47. Accordingly, at the time of performing turn-off switching, a breakdown strength due to current concentration in the peripheral region 18 can be enhanced whereby a high turn-off cut-off resistance can be acquired.

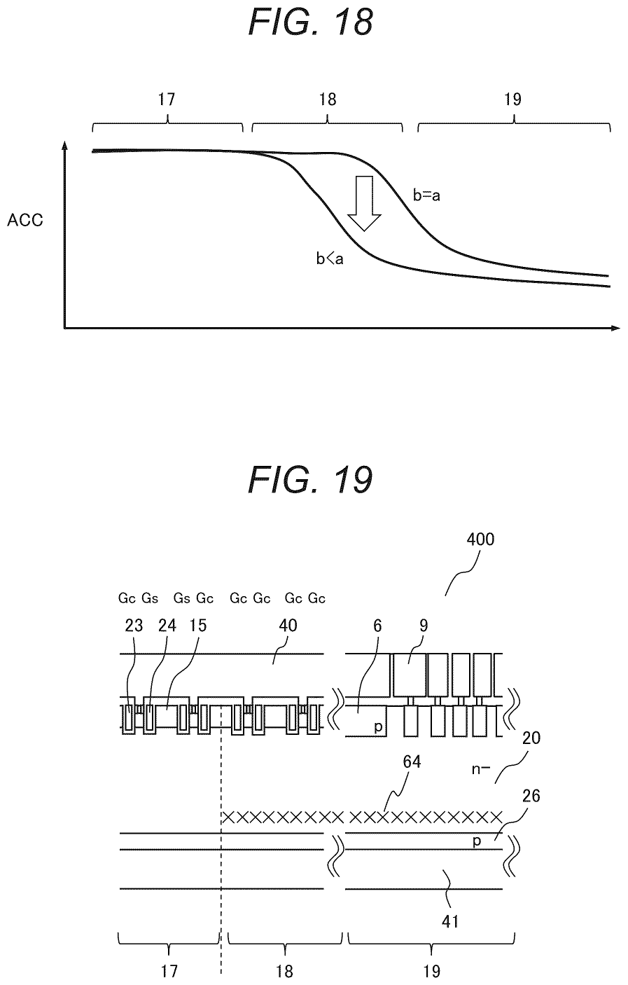

FIG. 18 is a view illustrating a profile distribution of accumulated carrier concentration ACC in the semiconductor device 300 during the high conduction period 46. By adopting the configuration where the relationship of b<a is established by arranging the carrier control gate (Gc) electrodes 23 in the peripheral region 18 at high density compared to the central region 17, the hole carriers 52 that are injected from the p type collector layer 26 are easily discharged from p type well layers 25 to the emitter electrode 40 in the peripheral region 18 and hence, the conductivity modulation in the peripheral region 18 can be suppressed whereby the cumulative carrier concentration profile becomes lower toward the terminal region 19 in a state where the cumulative carrier concentration profile is low compared to the arrangement where the relationship of b=a is established.

As has been described, in the semiconductor device 300 of this embodiment, the distance between the p type well layers 25 in the peripheral region 18 is narrower than the distance between the p type well layers 25 in the central region 17.

Accordingly, the carrier concentration in the peripheral region 18 and the carrier concentration in the terminal region 19 during the low conduction period 47 are further lowered and hence, in the turn-off switching performed thereafter, it is possible to induce an advantageous effect that a breakdown strength due to current concentration in the peripheral region 18 can be further enhanced.

### Fourth Embodiment

A semiconductor device 400 of an insulation gate type (gate control type) according to a fourth embodiment of the present invention is described with reference to FIG. 19 to FIG. 21. FIG. 19 is a cross-sectional view of the semiconductor device 400 according to this embodiment.

As illustrated in FIG. 19, in the semiconductor device 400 according to this embodiment, a carrier lifetime reduction layer 64 is disposed in an n-type drift layer 20 in a peripheral region 18 and a terminal region 19. The carrier lifetime reduction layer 64 is generated by crystal defects generated by the irradiation of a carrier lifetime killer of light ions such as helium and proton. The carrier lifetime reduction layer 64 has an advantageous effect of suppressing the conductivity modulation in the region due to the local introduction of the region.

In this embodiment, the carrier lifetime reduction layer 64 does not exist in the central region 17 and hence, an effect on a conduction loss during the high conduction period is limited and hence, an effect on a performance of a low conduction loss that the double gate type IGBT of the present invention possesses is small. On the other hand, by introducing the carrier lifetime reduction layer 64 into the peripheral region 18 and the terminal region 19, the conductivity modulation in the peripheral region 18 and the terminal region 19 can be suppressed.

Accordingly, the accumulated carrier concentration during the high conduction period 46 can be reduced and, at the same time, in the low conduction period 47, an effect of discharging the holes 52 from carrier control gate (Gc) electrodes 23 is added and hence, the carrier concentration in the peripheral region 18 can be further reduced compared to the first to the third embodiments. Accordingly, at the time of performing the turn-off switching, a breakdown strength due to current concentration in the peripheral region 18 can be further enhanced whereby a higher turn-off cut-off resistance can be acquired.

### Modification 3

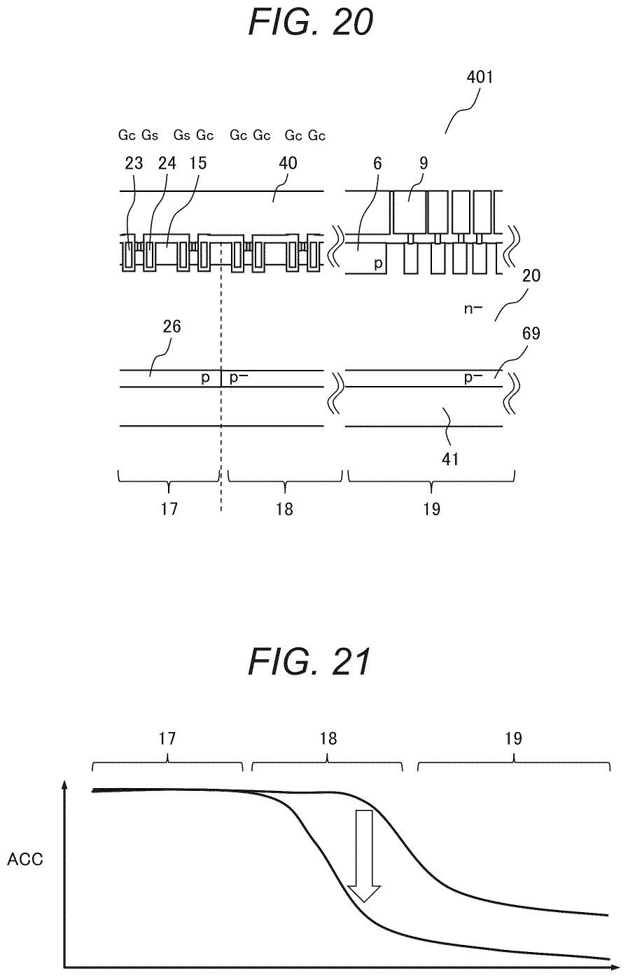

FIG. 20 illustrates another modification of the semiconductor device 400 illustrated in FIG. 19.

In the modification illustrated in FIG. 20, with respect to impurity concentration in a p type collector layer that is in contact with an n-type drift layer 20, impurity concentration in a peripheral region 18 and impurity concentration in a terminal region 19 are set low compared to impurity concentration in a central region 17. The p type collector layer is a layer into which holes 52 are injected when the IGBT is in a conduction state, and injection efficiency is lowered as the concentration is lowered.

In FIG. 20, by setting the concentration in the p type collector layer 26 in the central region 17 high and by setting the concentration in the p type collector layer 69 in the peripheral region 18 and the terminal region 19 low, a conduction loss during a high conduction period 46 is not affected and hence, it is possible to maintain a performance on a low conduction loss that the double gate type IGBT of the present invention possesses. On the other hand, by reducing the concentration in the p type collector layer 69 in the peripheral region 18 and the terminal region 19, conductivity modulation in the peripheral region 18 and the conductivity modulation in the terminal region 19 can be suppressed.

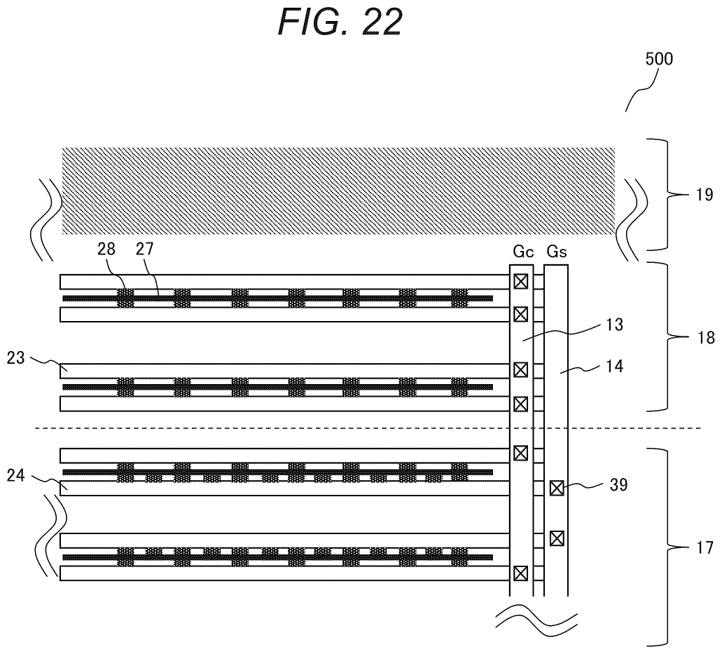

FIG. 21 is a view illustrating a profile distribution of accumulated carrier concentration ACC in the semiconductor devices 400 and 401 during the high conduction period 46 having the configuration illustrated in FIG. 19 and FIG. 20. By decreasing a carrier lifetime, or by decreasing the concentration of the p type collector layer, or by adopting both operations in the peripheral region 18 and the terminal region 19 compared to the central region 17, the conductivity modulation in the peripheral region 18 and the terminal region 19 can be suppressed and hence, the structure in the modification 3 exhibits low concentration compared to the structures illustrated in the first embodiment to the third embodiment. Accordingly, the carrier concentration in the peripheral region 18 and the carrier concentration in the terminal region 19 in the low conduction period 47 becomes further lower concentration. Accordingly, it is possible to induce an advantageous effect that, in turn-off switching performed thereafter, a breakdown strength due to current concentration in the peripheral region 18 can be further increased.

The configurations illustrated in FIG. 19 and FIG. 20 are applicable to the plan layouts illustrated in the first embodiment to the third embodiment.

### Fifth Embodiment

An insulation gate type (gate control type) semiconductor device 500 according to a fifth embodiment of the present invention is described with reference to FIG. 22. FIG. 22 is a plan layout view of the semiconductor device 500 of this embodiment, and describes gates extending in the longitudinal direction.

The arrangement of p type electricity supply layers 27 and n type emitter layers 28 that are connected with an emitter electrode 40 is described in FIG. 22. The n type emitter layers 28 are, when the IGBT is in a conduction state, regions where electrons 51 are injected into an n-type drift layer 20. In this embodiment, density of the n type emitter layer 28 that is in contact with carrier control gate (Gc) electrodes 23 per unit area is set lower than density of the n type emitter layers 28 that are in contact with switching gate (Gs) electrodes 24 per unit area.

That is, the semiconductor device 500 adopts the configuration where the area density of the n type emitter layers 28 in the peripheral region 18 is reduced compared to the area density of the n type emitter layers 28 in the central region 17.

As has been described above, in the semiconductor device 500 of this embodiment, as viewed in a plan view, a rate of a portion where the n type emitter layers 28 are disposed with respect to the carrier control gate (Gc) electrodes 23 in the peripheral region 18 by way of a gate insulation film 29 is smaller than a rate of a portion where the n type emitter layers 28 are disposed with respect to the switching gate (Gs) electrodes 24 in the central region 17 by way of the gate insulation film 29.

According to this embodiment, it is possible to reduce an electron injection efficiency from the peripheral region 18 during the low conduction period 47 and hence, the conductivity modulation in the peripheral region 18 and the terminal region 19 on the n-type drift layer 20 can be suppressed whereby the accumulated carrier concentration can be further reduced compared to the configurations from the first embodiment to the fourth embodiment. Accordingly, at the time of performing turn-off switching, a breakdown strength due to current concentration in the peripheral region 18 can be further enhanced and hence, it is possible to acquire a higher turn-off cut-off resistance.

Also in FIG. 22, a switching gate (Gs) wiring 14 and a carrier control gate (Gc) wiring 13 are configured to extend only on the peripheral region 18 and the central region 17. However, for the purpose of reducing a wiring resistance or for the purpose of facilitating the supply of electricity, such wirings may be provided to the terminal region 19.

Further, the configuration illustrated in FIG. 22 is applicable to the plane layouts illustrated in the first embodiment to the third embodiment.

### Sixth Embodiment

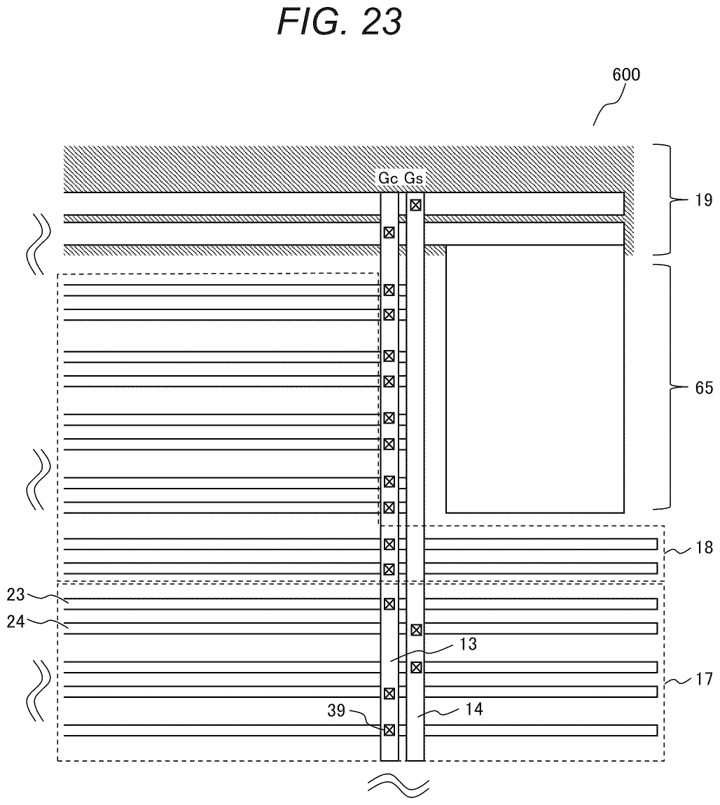

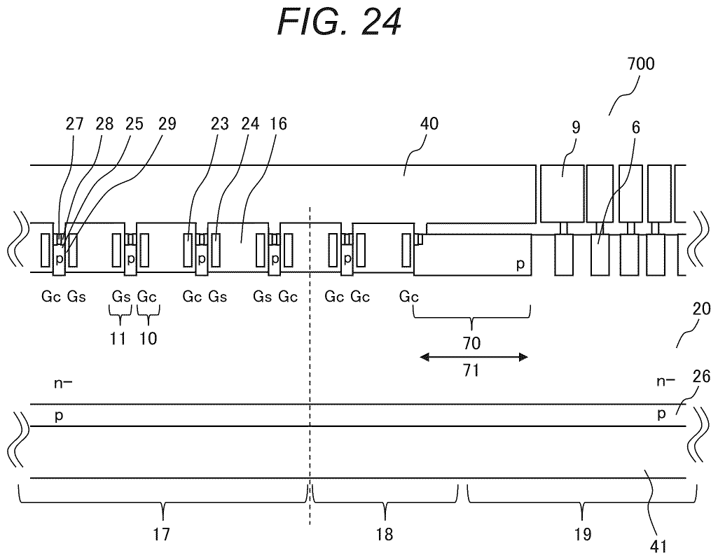

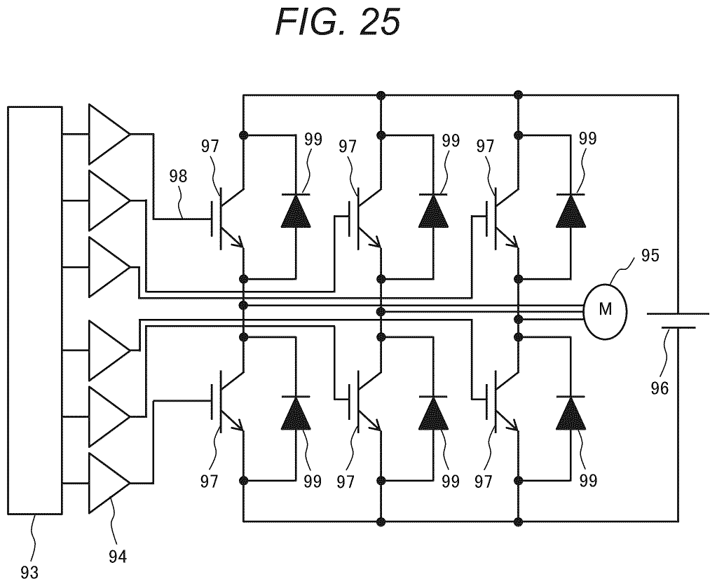

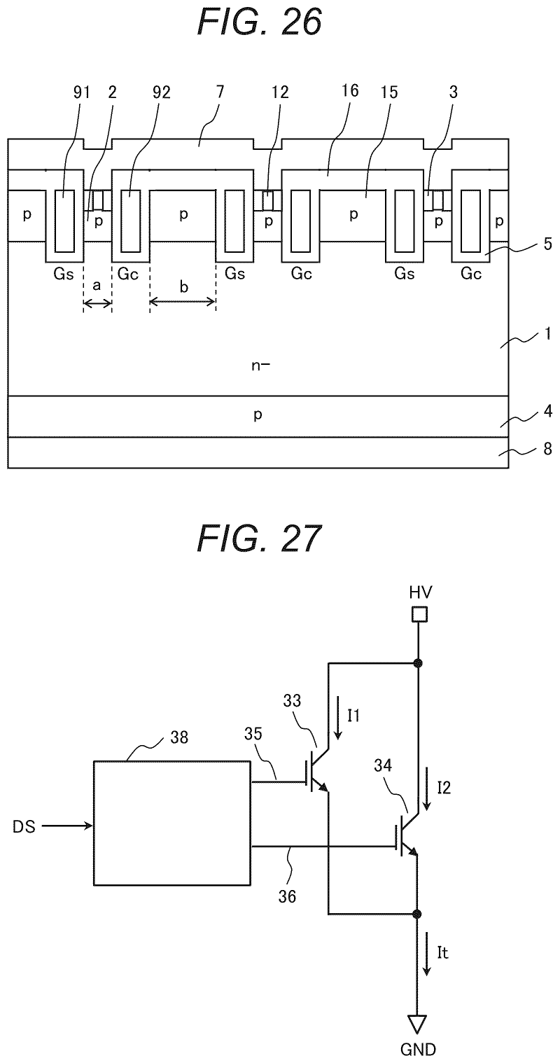

An insulation gate type (gate control type) semiconductor device 600 according to a sixth embodiment of the present invention is described with reference to FIG. 23. FIG. 23 is a plan layout view of the semiconductor device 600 of this embodiment, and illustrates a periphery of a gate pad region.

As illustrated in FIG. 23, in the semiconductor device 600 of this embodiment, the gate pad region 65 is disposed in a portion inside a terminal region 19 disposed on a periphery of a chip, a peripheral region 18 is disposed adjacently to the terminal region 19 and inside the gate pad region 65, and a central region 17 is disposed inside the peripheral region 18.

As illustrated in FIG. 23, the semiconductor device 600 of this embodiment is configured such that the gate pad region 65 is disposed adjacently to the terminal region 19 and the peripheral region 18.

Also in the gate pad region 65, an n-type drift layer 20 and a p type collector layer 26 are disposed shared in common by the peripheral region 18, the central region 17, and the terminal region 19 are disposed below the gate pad region 65. Accordingly, in a high conduction period 46, the conductivity modulation is generated also in the n-type drift layer 20 in the gate pad region 65 and hence, the carrier concentration is increased.

During a low conduction period 47, due to carrier control gate (Gc) electrodes 23 in the peripheral region 18 disposed on the periphery of the gate pad region 65, holes 52 are extracted and hence, the conductivity modulation in the gate pad region 65 is suppressed. In the turn-off switching preformed thereafter, the current concentration toward the peripheral region 18 is suppressed and hence, a breakdown strength of the semiconductor device 600 can be enhanced.

Accordingly, at the time of performing turn-off switching, a breakdown strength due to current concentration in the peripheral region 18 can be further enhanced and hence, it is possible to acquire a higher turn-off cut-off resistance.

In FIG. 23, one gate pad region 65 is illustrated. However, in the actual semiconductor device 600 of this embodiment, two gate pad regions 65 consisting of the gate pad region 65 for a switching gate (Gs) wiring 14 and a gate pad region 65 for a carrier control gate (Gc) wiring 13 exist, and the configuration of this embodiment is applied to both gate pad regions 65.

Also, the switching gate (Gs) wiring 14 and the carrier control gate (Gc) wiring 13 are configured to extend only on the peripheral region 18 and the central region 17. However, for the purpose of reducing a wiring resistance or for the purpose of facilitating the supply of electricity, such wirings may be provided to the terminal region 19.

Further, although the gate pad region 65 is disposed adjacently to the terminal region 19, the peripheral region 18 may be disposed between the terminal region 19 and the gate pad region 65.

Further, this embodiment can be applied to the plan layouts illustrated in the first embodiment to the third embodiment. Further, by applying the carrier lifetime reduction layer 64 and the low concentration p type collector layer 69 illustrated in the fourth embodiment to the gate pad region 65, it is possible to acquire an advantageous effect of enhancing a turn-off cut-off resistance.

### Seventh Embodiment

An insulation gate type (gate control type) semiconductor device 700 according to a seventh embodiment of the present invention is described with reference to FIG. 24. FIG. 24 is a cross-sectional view of the semiconductor device 700 of this embodiment,

As illustrated in FIG. 24, the semiconductor device 700 of this embodiment adopts, as a shape of gate electrode, a side gate shape where surfaces of the gate electrodes on one side are in contact with p type well layers (emitter well layer) 25 by way of gate insulation films 29 and surfaces of the gate electrodes on the other side are in contact with an insulation film (a thick oxide film 16) in a state where neither the p type well layers (emitter well layers) 25 nor an n-type drift layer 20 exist.

In the trench gate shapes described in the first embodiment to the sixth embodiment, in addition to an MOS capacitance formed by the gate electrodes, the gate insulation film 29 and the n-type drift layer 20 below the trench gates, an MOS capacitance formed of a p type floating layer (or an n-type drift layer) 15 that is disposed on a surface on a side opposite to a surface that faces the p type well layers 25, the gate insulation film 29 and gate electrodes is disposed in parallel to the above-mentioned MOS capacitance.

With such a configuration, in the trench gate type semiconductor, the MOS capacitance functions as a feedback capacitance and a value of the MOS capacitance are large. Accordingly, when the IGBT performs turn-off switching or turn-on switching, a mirror period during which this capacitance is charged is generated and hence, a change in current or voltage at a high speed is interrupted thus becoming a cause that increases a loss.

On the other hand, in the semiconductor devices having a side gate shape, on a surface on a side opposite to a surface that faces the p type well layers 25 (that is, the other surface), a thick insulation film 16 is disposed and hence, a capacitance component does not exist. Accordingly, the feedback capacitance is formed of the only the MOS capacitance that is formed by the gate electrodes, the gate insulation film 29 and the n-type drift layer 20 disposed below the side gate and hence, its capacitance value is small compared to the trench gate type.

Accordingly, compared to the trench gate type, at the time of performing switching, a current or voltage changes at a higher speed and hence, a switching loss is reduced. Accordingly, even in a case where the present invention is applied to the IGBT having the side gate structure, in the same manner as the first embodiment, it is possible to acquire an advantageous effect of the present invention that both a low loss performance and a higher turn-off cut-off resistance obtained by suppressing the generation of electric power at the time of switching in the peripheral region 18 can be induced. That is, it is possible to realize the double gate type IGBT which can realize both low loss and high output.

A p type layer 70 disposed in a boundary between the peripheral region 18 and the terminal region 19 illustrated in FIG. 24 is provided as a region that functions as a resistance against hole carriers 52 at the time of performing turn-off switching, and reduces a current concentrated in the peripheral region 18.

According to this embodiment, the hole concentration in the peripheral region 18 and the terminal region 19 can be reduced during the low conduction period 47 and hence, a current in the peripheral region 18 and the terminal region 19 can be reduced whereby a length 71 of the p type layer 70 can be shortened. That is, by applying the present invention to the semiconductor device, an area of the entire semiconductor device formed of the central region 17, the peripheral region 18 and the terminal region 19 can be reduced thus also giving rise to an effect of miniaturizing the semiconductor device.

The present invention is applicable to a semiconductor device, a drive device of a semiconductor circuit and a power conversion device suitable for these devices used in a wide range from a small power equipment such an air conditioner or an electronic oven, to a large power equipment such as an inverter used in an automobile, a railway or steel making plant.

The present invention is not limited to the above-mentioned embodiments, and includes various modifications. For example, the above-mentioned embodiments are described in detail for providing the description that facilitates the understanding of the present invention, and it is not always the case that the present invention is limited to the semiconductor device that includes all constitutional elements described above. In addition, part of the configuration of one embodiment can be replaced with the configurations of other embodiments, and in addition, the configuration of the one embodiment can also be added with the configurations of other embodiments. In addition, part of the configuration of each of the embodiments can be subjected to addition, deletion, and replacement with respect to other configurations.

### LIST OF REFERENCE SIGNS

1: n-type drift layer
2: p type well layer
3: n type emitter layer
4: p type collector layer
5: gate insulation film (oxide film)
6: p type high concentration layer
7: emitter electrode
8: collector electrode
9: floating electrode
10: carrier control gate (Gc)
11: switching gate (Gs)
12: p type electricity supply layer
13: carrier control gate (Gc) wiring
14: switching gate (Gs) wiring
15: p type floating layer or n-type drift layer
16: thick insulation film
17: central region (cell)
18: peripheral region (cell)
19: terminal region
20: n-type drift layer
23: carrier control gate (Gc) electrode
24: switching gate (Gs) electrode
25: p type well layer
26: p type collector layer
27: p type electricity supply layer
28: n type emitter layer
29: gate insulation film (gate oxide film)
30: electric power loss of double gate type IGBT of present invention
31: electric power loss of conventional double gate type IGBT
32: cell disposed in boundary with terminal region 19
33: IGBT using low ON voltage
34: IGBT using high ON voltage
35: gate of IGBT 33 using low ON voltage
36: gate of IGBT 34 using high ON voltage
38: control circuit of gate
39: contact layer
40: emitter electrode
41: collector electrode
42: dummy gate region
44: gate driver
45: gate driver
46: high conduction period
47: low conduction period
48: conduction period
49: non conduction period
50: turn-off switching
51: carriers of electrons
52: carriers of holes
53: conductivity modulation
54: profile of accumulated carriers having low concentration temporarily
55: profile of accumulated carriers having extremely low concentration temporarily
56: accumulated carriers having high concentration
57: turn-off switching waveform of conventional double gate type IGBT
58: turn-off switching waveform of double gate type IGBT of present invention
59: turn-off cut-off resistance of conventional double gate type IGBT
60: turn-off cut-off resistance of double gate type IGBT of present invention
61: performance of conventional IGBT formed of one kind of gate
62: performance of conventional double gate type IGBT
63: performance of double gate type IGBT of present invention
64: carrier lifetime reduction layer
65: gate pad region
69: low concentration p type collector layer
70: p type layer in boundary between peripheral region and terminal region
71: length of p type layer in boundary between peripheral region and terminal region
91: insulation gate electrode (Gs)
92: insulation gate electrode (Gc)
93: control circuit
94: drive circuit
95: inductive load
96: direct current power source
97: IGBT
98: insulation gate terminal
99: diode
100: semiconductor device (double gate type IGBT)
200: semiconductor device (double gate type IGBT)
300: semiconductor device (double gate type IGBT)
400: semiconductor device (double gate type IGBT)
401: semiconductor device (double gate type IGBT)
500: semiconductor device (double gate type IGBT)
600: semiconductor device (double gate type IGBT)
700: semiconductor device (double gate type IGBT)
1000: conventional semiconductor device (IGBT)
I/V: current/voltage
I_{C}: collector current
V_{CE}: collector-emitter voltage
GP: generated power
STD: turn-off cut-off resistance
V: voltage
MRV: maximum rated voltage
RU: range of use
SL: switching loss
ACC: accumulated carrier concentration during high conduction period

1. A semiconductor device comprising:
a switching gate and a carrier control gate that are independently driven from each other, wherein
the semiconductor device further includes, in a state where the semiconductor device is viewed in a plan view, a central region cell, a peripheral region cell surrounding a whole circumference of the central region cell, and a terminal region surrounding a whole circumference of the peripheral region cell,
the central region cell includes a switching element that has the switching gate and the carrier control gate,
the peripheral region cell is disposed between the central region cell and the terminal region, and
a gate of a switching element in the peripheral region cell is constituted of only the carrier control gate.

2. The semiconductor device according to claim 1, wherein,
an operation state of the semiconductor device has:
a first state where a voltage by which an inversion layer is formed in the switching element is applied to the switching gate and the carrier control gate,
a second state where a voltage by which the inversion layer is formed in the switching element is applied to the switching gate, and a voltage by which an accumulation layer is formed in the switching element is applied to the carrier control gate; and
a third state where a voltage by which an accumulation layer is formed in the switching gate is applied to the switching gate and carrier control gate, and
in a case where the semiconductor device is shifted from a conduction state to a non-conduction state, the semiconductor device is shifted in an order of the first state, the second state and the third state.

3. The semiconductor device according to claim 1, wherein,
as viewed in a plan view of the semiconductor device, a ratio of a portion where an emitter layer is disposed with respect to the carrier control gate in the peripheral region cell by way of a gate insulation film is smaller than a ratio of a portion where the emitter layer is disposed with respect to the switching gate in the central region cell by way of the gate insulation film.

4. The semiconductor device according to claim 1, wherein,
the switching element in the central region cell includes an emitter layer and a well layer disposed between the switching gate and the carrier control gate,
the switching element in the peripheral region includes the carrier control gate, the emitter layer and the well layer, and
a distance between the well layers in the peripheral region cell is narrower than a distance between the well layers in the central region cell.

5. The semiconductor device according to claim 1, wherein,
the central region cell, the peripheral region cell and the terminal region have a commonly shared drift layer, and
a carrier lifetime killer layer is disposed in the drift layer in the peripheral region cell and in the drift layer in the terminal region.

6. The semiconductor device according to claim 1, wherein,
the central region cell, the peripheral region cell and the terminal region have a commonly shared drift layer,
the semiconductor device includes a first carrier injection layer through which carriers are injected in the drift layer in the central region cell, and a second carrier injection layer through which the carriers are injected in the drift layer in the peripheral region cell and the terminal region, and
impurity concentration in the second carrier injection layer is low compared to impurity concentration in the first carrier injection layer.

7. The semiconductor device according to claim 1,
further comprising a gate pad region disposed adjacently to the peripheral region cell and the terminal region.

8. The semiconductor device according to claim 4, wherein,
the switching gate and the carrier control gate have a trench gate shape or a side gate shape.

9. The semiconductor device according to claim 4, wherein,
as viewed in a plan view of the semiconductor device, the switching gate extends also over the peripheral region cell, and
the switching gate in the peripheral region cell is a dummy gate where no emitter layer is formed by way of the gate insulation film.

10. A power conversion device configured to use the semiconductor device described in claim 1.
